(19) United States
(12) Patent Application Publication
(10) Pub. No.: US 2018/0179815 A1
(43) Pub. Date: Jun. 28, 2018

(54) SHUTTER CONTROL

(71) Applicant: Bruce Stanley Gunton, Staffordshire (GB)

(72) Inventor: Bruce Stanley Gunton, Staffordshire (GB)

(21) Appl. No.: 15/387,978

(22) Filed: Dec. 22, 2016

(51) Int. Cl. E06B 9/68; H03H 7/01

(52) U.S. Cl. CPC E06B 9/68; E06B 2009/6809; E06B 2009/6872; H03H 7/0138

(57) ABSTRACT

A shutter control apparatus, including: a tunable filter arrangement, having a tunable passband, configured to filter a signal derived at least in part from an electric motor, wherein the electric motor is for driving a moveable shutter and the signal comprises pulses that have a variable frequency and are derived from operation of a commutator of the electric motor; and control circuitry configured to: determine at least one electrical parameter associated with the electric motor; set the tunable passband based, at least in part, on the at least one electrical parameter; determine pulses in the signal passing through the tunable filter arrangement; and determine a position of the moveable shutter based on the determined pulses.

### TECHNOLOGICAL FIELD

Embodiments of the present invention relate to shutter control. In particular, they relate to control of roller shutter door.

### BACKGROUND

A direct current (DC) motor may be used to drive a shutter for closing an aperture. An example of such a shutter is a roller shutter door for opening and closing a door aperture.

### BRIEF SUMMARY

According to various, but not necessarily all, embodiments of the invention there is provided a shutter control apparatus, comprising: a tunable filter arrangement, having a tunable passband, configured to filter a signal derived at least in part from an electric motor, wherein the electric motor is for driving a moveable shutter and the signal comprises pulses that have a variable frequency and are derived from operation of a commutator of the electric motor; and control circuitry configured to: determine at least one electrical parameter associated with the electric motor; set the tunable passband based, at least in part, on the at least one electrical parameter; determine pulses in the signal, after the signal has passed through the tunable filter arrangement; and determine a position of the moveable shutter based on the determined pulses.

The tunable passband may be set such that the pulses in the signal are maintained when the signal passes through the tunable filter arrangement.

The control circuitry may be configured to determine the position of the moveable shutter by counting the pulses in the signal.

The tunable filter arrangement may be configured to attenuate mains ripple in the signal. The tunable filter arrangement may comprise a fixed frequency high pass filter configured to attenuate mains ripple in the signal.

The tunable filter arrangement may be configured to attenuate noise in the signal that is different from the pulses and derived from operation of the commutator of the electric motor. The tunable filter arrangement may comprise a tunable filter, with a bandwidth of less than 100 Hz, configured to attenuate the noise in the signal.

The shutter control apparatus may further comprise an n-channel field effect transistor, arranged to modulate electric current supplied to the electric motor, having a source terminal electrically connected to a positive power supply terminal and a drain terminal electrically connected to the electric motor.

The control circuitry may be configured to determine a change in the at least one electrical parameter; and to reset the tunable passband in response to the determined change in the at least one electric parameter.

The control circuitry may be configured to set the tunable passband by referring to a look up table stored in memory.

The electrical parameter(s) may vary over time. The at least one electrical parameter may include a voltage parameter. The voltage parameter may indicate a supply voltage for the electric motor.

The electrical parameter(s) may include an electrical load parameter. The electrical load parameter may indicate an electrical load of the electric motor.

The electrical parameter(s) may include a pulse width modulation parameter. The pulse width modulation parameter may be associated with the modulation of electric current supplied to the electric motor.

According to various, but not necessarily all, embodiments of the invention there is provided a method, comprising: filtering a signal derived at least in part from an electric motor, wherein the electric motor is for driving a moveable shutter and the signal comprises pulses that have a variable frequency and are derived from operation of a commutator of the electric motor; determining at least one electrical parameter associated with the electric motor; setting the tunable passband based, at least in part, on the at least one electrical parameter; determine pulses in the signal, after the signal has passed through the tunable filter arrangement; and determine a position of the moveable shutter based on the determined pulses.

According to various, but not necessarily all, embodiments of the invention there is provided a non-transitory computer readable medium comprising computer program instructions that, when executed by at least one processor, enable the method described above to be performed.

According to various, but not necessarily all, embodiments of the invention there is provided a shutter control apparatus, comprising: an electric motor, for driving a moveable shutter, having an electric motor current in operation from which a voltage signal is derived that comprises pulses having a variable frequency which are derived from operation of a commutator of the electric motor; a fixed frequency high pass filter configured to filter out mains ripple from the voltage signal; a tunable filter, having a tunable passband, configured to filter the voltage signal after the voltage signal has been filtered by the fixed frequency high pass filter; and control circuitry configured to:

determine an electric motor supply voltage, an electrical load of the electric motor, and a pulse width modulation parameter associated with the modulation of the electric motor current; set the tunable passband based on the electric motor supply voltage, the electrical load of the electric motor, and the pulse width modulation parameter associated with the modulation of the electric motor current; and determine a position of the moveable shutter by counting pulses in the voltage signal after the voltage signal has passed through the tunable filter.

According to various, but not necessarily all, embodiments of the invention there is provided examples as claimed in the appended claims.

### BRIEF DESCRIPTION

For a better understanding of various examples that are useful for understanding the detailed description, reference will now be made by way of example only to the accompanying drawings in which:

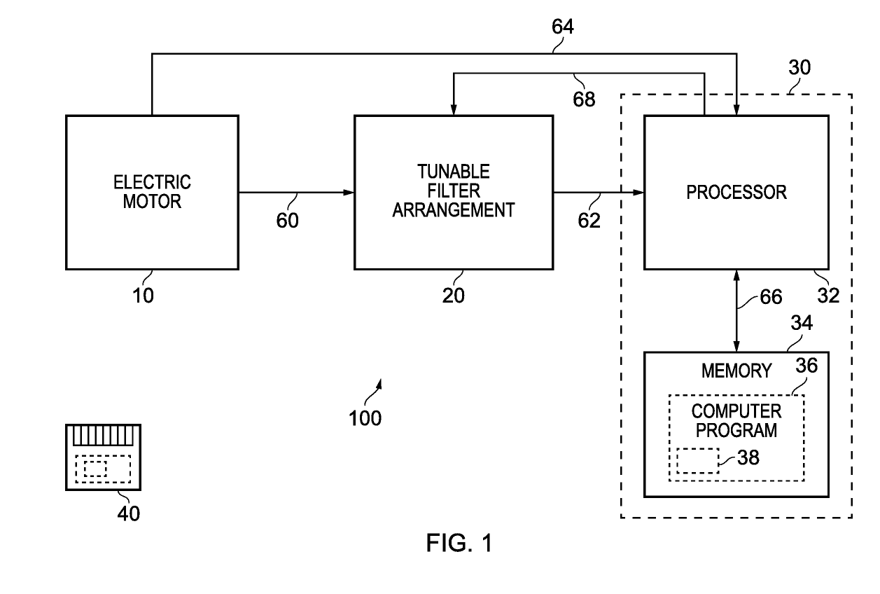

FIG. 1 illustrates a first schematic of a shutter control apparatus;

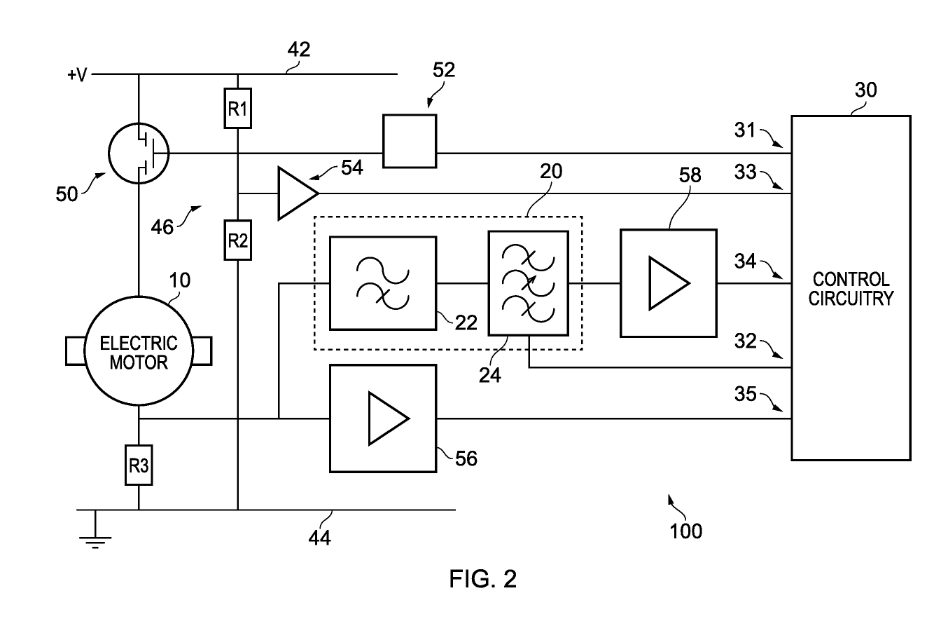

FIG. 2 illustrates a second schematic of the shutter control apparatus;

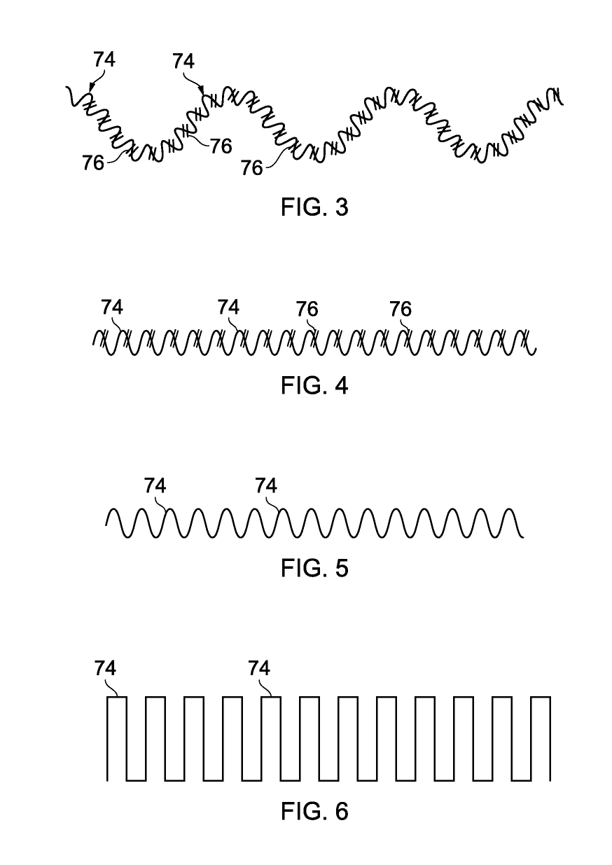

FIG. 3 illustrates a voltage signal, derived at least in part from an electric motor, prior to filtering;

FIG. 4 illustrates the voltage signal after it has been filtered by a high pass filter and prior to filtering by a tunable filter;

FIG. 5 illustrates the voltage signal after filtering by the high pass filter and the tunable filter;

FIG. 6 illustrates the voltage signal after filtering by the high pass filter and the tunable filter and after amplification; and

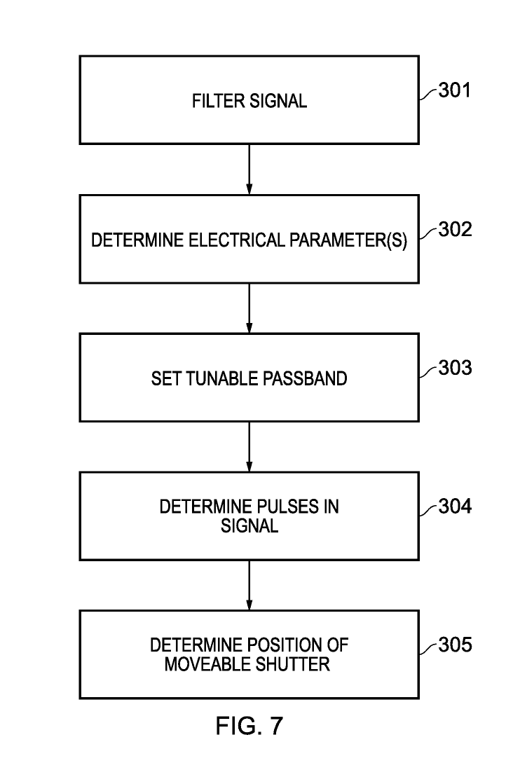

FIG. 7 illustrates a flow chart of a method.

### DETAILED DESCRIPTION

Embodiments of the invention relate to a shutter control apparatus 100 for controlling movement of a shutter, such as a roller shutter door. The roller shutter door may be for opening and closing a door aperture.

FIG. 1 illustrates a first schematic of the shutter control apparatus 100. The shutter control apparatus 100 comprises an electric motor 10, a tunable filter arrangement 20 and control circuitry 30.

The electric motor 10 is for coupling to and driving a moveable shutter such as a roller shutter door. It may, for example, be a DC motor. The electric motor 10 comprises a commutator and brushes. During operation of the electric motor, relative movement (e.g. rotation) of the commutator and the brushes causes an electrical connection between the commutator and the brushes to be periodically broken and restored. This causes the magnitude of the current passing through the electric motor 10 to rise and fall periodically as the motor 10 turns, creating pulses in the current. The frequency of the pulses depends on the frequency at which the electric motor 10 is running. A variation in the speed at which the electric motor 10 is running causes a variation in the frequency of the pulses.

The tunable filter arrangement 20 has a tunable passband. It is configured to filter a signal derived at least in part from the electric motor 10. The signal is illustrated schematically by the arrow labeled with the reference numeral 60.

The signal derived from the electric motor 10 comprises the pulses described above, which have a variable frequency and are derived from operation of the commutator of the electric motor 10.

The control circuitry 30 is configured to determine at least one electrical parameter associated with the electric motor 10. This is illustrated schematically by the arrow 64 in FIG. 1. The electrical parameter may include a voltage parameter, an electrical load parameter and/or a pulse width modulation parameter.

The voltage parameter may indicate a supply voltage for the electric motor 10. The electrical load parameter may indicate an electrical load of the electric motor 10. The pulse width modulation parameter may be associated with the modulation of electric current supplied to the electric motor 10.

The control circuitry 30 is configured to set the tunable passband of the tunable filter arrangement 20 based, at least in part, on the at least one electrical parameter. This is illustrated schematically by the arrow labeled with the reference numeral 68 in FIG. 1.

The control circuitry 30 is further configured to determine pulses in the signal, after the signal has passed through the tunable filter arrangement 20, and to determine a position of the moveable shutter based on the determined pulses. The position of the moveable shutter may, for example, be determined by counting the pulses in the determined signal. The arrow labeled with the reference numeral 62 in FIG. 1 schematically illustrates the filtered signal being provided to the control circuitry 30 which enables the control circuitry 30 to determine a position of the moveable shutter.

The control circuitry 30 may be implemented in hardware alone, have certain aspects in software including firmware alone or can be a combination of hardware and software (including firmware). The control circuitry 30 may also comprise one or more output interfaces via which data and/or commands are output by the control circuitry 32 and one or more interfaces via which data and/or commands are input into the control circuitry 30.

In the illustrated example, the control circuitry 30 comprises at least one processor 32 and memory 34. The processor 32 is configured to read from and write to the memory 34, as indicated schematically by the arrow labeled with the reference numeral 66.

The memory 34 stores a computer program 36 comprising computer program instructions (computer program code) 38 that controls the operation of the apparatus 100 when loaded into the processor 32. The computer program instructions 38, of the computer program 36, provide the logic and routines that enables the apparatus 100 to perform the method illustrated in FIG. 7. The processor 32 by reading the memory 34 is able to load and execute the computer program 36.

As illustrated in FIG. 1, the computer program 36 may arrive at the apparatus 100 via any suitable delivery mechanism 40. The delivery mechanism 40 may be, for example, a non-transitory computer-readable storage medium, a computer program product, a memory device, a record medium such as a compact disc read-only memory (CD-ROM) or digital versatile disc (DVD) or a different article of manufacture that tangibly embodies the computer program 36. The delivery mechanism 40 may be a signal configured to reliably transfer the computer program 36.

Although the memory 34 is illustrated as a single component/circuitry it may be implemented as one or more separate components/circuitry some or all of which may be integrated/removable and/or may provide permanent/semi-permanent/dynamic/cached storage.

Although the processor 32 is illustrated as a single component/circuitry it may be implemented as one or more separate components/circuitry some or all of which may be integrated/removable. The processor 32 may be a single core or multi-core processor.

FIG. 2 illustrates a second schematic of the shutter control apparatus 100 that is, in some respects, more detailed than that illustrated in FIG. 1. The shutter control apparatus 100 comprises the same electric motor 10, tunable filter arrangement 20 and control circuitry 30 as that described above in relation FIG. 1. In addition, the apparatus 100 comprises a number of other components, including voltage supply rails 42, 44, a field effect transistor (FET) 50, a voltage divider 46 comprising resistors labeled R1 and R2, a current sense resistor R3, and first, second and third buffer amplifiers 54, 56, 58. The tunable filter arrangement 20 is illustrated as comprising two filters: a fixed frequency high pass filter 22 and a tunable filter 24 having a tunable passband.

The control circuitry 30 is illustrated as comprising first and second output interfaces 31, 32 and first, second and third input interfaces 33, 34, 35. Where the control circuitry 30 comprises at least one processor 32 and memory 34 (as illustrated in FIG. 1), the output and input interfaces 31-35 are provided by the at least one processor 32.

Electric power is supplied to the electric motor 10 by connecting the motor 10 between a positive power supply terminal/rail 42 and a ground terminal/rail 44. The FET 50 is connected in series with the electric motor 10, between the positive supply rail 42 and the motor 10. In this example, the FET 50 is an n-channel metal-oxide-semiconductor field effect transistor (MOSFET). The source terminal of the n-channel MOSFET 50 is electrically connected to the positive supply rail 42 and the drain terminal is electrically connected to a terminal of the electric motor 10. The gate terminal of the MOSFET 50 is operatively connected to the first output interface 31 of the control circuitry 30. A driver 52 is connected between the gate terminal of the MOSFET 50 and the first output interface 31 of the control circuitry 30.

The control circuitry 30 is configured to modulate the electric current supplied to the electric motor 10 by causing a voltage to be applied to the gate terminal of the MOSFET 50. In this example, the control circuitry 30 provides an output to the driver 52 which responds by periodically applying a voltage to the gate terminal of the MOSFET 50, causing the modulation of the current. The modulation technique used may be pulse width modulation (PWM). The control circuitry 30 may be configured to adjust the duty cycle of the PWM to alter the speed of the electric motor 10, and therefore also the speed at which the movable shutter moves.

The supply voltage for the electric motor 10 is also input into the voltage divider 46, which reduces the size of the voltage signal. The output of the voltage divider 46 is provided to the first input interface 33 of the control circuitry 30 via the first buffer amplifier 54. The purpose of the voltage divider 46 is to reduce the voltage signal to a level that is appropriate for input into the control circuitry 30. The first buffer amplifier 54 amplifies the voltage signal before it is input into the first interface 33 of the control circuitry 30. The magnitude of the voltage signal provided to the first input interface 33 of the control circuitry 30 at any particular instance in time indicates the magnitude of the supply voltage for the electric motor 10 at that time.

The electric current passing through the electric motor 10 is sensed using a current sense resistor R3 which is connected in series with the electric motor 10, between the motor 10 and the ground rail 44. The current sense resistor R3 translates this motor current into a voltage signal that is indicative of the motor current and which can be measured and monitored.

The voltage signal produced by the current sense resistor R3 is provided to the third input interface 35 of the control circuitry 30 via the second buffer amplifier 56. The second buffer amplifier 56 amplifies the voltage signal before it is provided to the third input interface 35 of the control circuitry 30. The magnitude of the voltage signal provided to the third input interface 35 of the control circuitry 30 at any particular instance in time indicates the magnitude of the motor current at that time.

The voltage signal produced by the current sense resistor R3 is also provided to the tunable filter arrangement 20. FIG. 3 illustrates an example of the voltage signal produced by the current sense resistor R3 which, as explained above, is indicative of the motor current. The voltage signal has an approximately sinusoidal form that arises from the presence of relatively low frequency mains supply ripple. In the US and Canada, mains supply ripple will be at a frequency of 120 Hz. Pulses 74 in the motor current, caused by the commutator of the electric motor 10 switching, are also present. The frequency of the pulses 74 in the motor current is dependent on the speed at which the electric motor 10 is running. The faster the electric motor 10 runs, the more frequently the commutator switches, resulting in pulses of a higher frequency. The slowest mode of operation of the electric motor 10 will result in commutator pulses of a first frequency and the fastest mode of operation of the electric motor 10 will result in commutator pulses of a second frequency, the second frequency being higher than the first frequency.

The first frequency is also likely to be higher than the frequency of the mains supply ripple. In some embodiments, the first frequency is in the region of 300 Hz and the second frequency is in the region of 1.2 kHz.

The voltage signal also exhibits short pulses 76 of very high frequency noise, arising from commutator contacts arcing, bouncing or the like.

The voltage signal is initially applied to the fixed frequency high pass filter 22 of the tunable filter arrangement 20 illustrated in FIG. 2. The fixed frequency high pass filter 22 is configured to filter out (attenuate) the mains supply ripple in the voltage signal without filtering out (attenuating) the commutator pulses. Thus, the fixed frequency high pass filter 22 has a cutoff frequency which is above the frequency of the mains supply ripple but below the frequency of the commutator pulses that are produced when the electric motor 10 is running in its slowest mode of operation. The cutoff frequency of the fixed high pass filter 22 may be greater than 120 Hz and lower than 300 Hz. In one example, the cutoff frequency is 270 Hz. The voltage signal input into fixed frequency filter 22 may be attenuated by at least 3 dB below the cutoff frequency.

FIG. 4 illustrates an example of the voltage signal after it has been filtered by the fixed frequency high pass filter 22 and prior to it being applied to the tunable filter 24. It can be seen in FIG. 4 that the mains supply ripple has been filtered out of the voltage signal but the commutator pulses 74 and the noise 76 derived from commutator contacts arcing, bouncing etc. remains. The tunable filter 24 is configured to filter out the noise 76 derived from commutator contacts arcing, bouncing etc. without filtering out the commutator pulses. However, as explained above, the frequency of the commutator pulses 74 varies depending on the speed at which the electric motor 10 is running and, also, a higher peak value of output voltage signal (the commutator pulses 74) can be obtained if the tunable filter 24 is tuned to the resonant frequency of the circuitry of the electric motor 10 (i.e. the inductance of the motor coil windings, the motor supply wires and associated capacitance).

As explained above, the control circuitry 30 is configured to receive a signal at the first input interface 33 that indicates the magnitude of the supply voltage for the electric motor 10 at an instance in time. The control circuitry 30 is also configured to receive a signal at the third input interface 35 that indicates the magnitude of the motor current at that instance in time. The manner in which the motor current is being modulated by the MOSFET 50 at that instance in time is also known to the control circuitry 30, because the modulation is being performed under the control of the control circuitry 30.

As explained above, the frequency of the commutator pulses 74 depends on the speed at which the electric motor 10 is running which, in turn, depends upon i) a voltage parameter in the form of the magnitude of the supply voltage for the electric motor 10, ii) an electrical load parameter in the form of the magnitude of the motor current and iii) a pulse width modulation parameter in the form of the magnitude of the pulse width modulation rate (duty cycle). For example, the speed of the electric motor 10 may, at least in some speed ranges, be directly proportional to each of i) to iii).

Each of i) to iii) can be considered to be an electrical parameter. The control circuitry 30 is configured to set the tunable passband of the tunable filter 24 based, at least in part, on at least one these electrical parameters. In some embodiments, the control circuitry 30 is configured to set the tunable passband of the tunable filter 24 based, at least in part, on two of these electrical parameters or all three of these electrical parameters.

In performing the above function, the control circuitry 30 is setting the tunable passband of the tunable filter 24 based on the expected frequency of the commutator pulses 74, which is determined from one or more of the electrical parameters i) to iii). In some embodiments, a look up table may be provided in the memory 34 of the control circuitry 30 which specifies how the passband of the tunable filter 24 should be set based on particular readings of the electrical parameters i) to iii). The lookup table may, for example, specify at least one of a lower cutoff frequency and a higher cutoff frequency for the tunable filter 24.

The electrical parameters i) to iii) vary over time. The control circuitry 30 is configured to monitor the electrical parameters periodically, over a period of time, and respond to changes in the electrical parameters during that period of time by resetting the tunable passband as necessary (e.g. on multiple occasions) according to the expected frequency of the commutator pulses 74.

In some embodiments, each time the passband is set, the bandwidth of the passband remains substantially the same. In other embodiments, the bandwidth of the passband is variable. A suitable bandwidth might be in the region of 50-60 Hz.

FIG. 5 illustrates an example of the voltage signal after filtering by the tunable filter 24. It can be seen that the noise derived from commutator contacts arcing, bouncing etc. has been attenuated but the commutator pulses 74 remain. The voltage signal output by the tunable filter 24 is provided to the third buffer amplifier 58. The third buffer amplifier 58 acts to convert the commutator pulses 74 into a square wave by amplifying the voltage signal to such an extent that clipping occurs. The resulting square wave voltage signal is then input into the control circuitry 30 via the second input interface 34.

FIG. 6 illustrates the voltage signal following amplification by the third buffer amplifier 58. The control circuitry 30 is configured to determine (square wave) pulses 74 in the signal that are received at the second interface 34 of the control circuitry 30 and to determine the position of a movable shutter based on the determined pulses 74.

As explained above, in operation, the electric motor 10 is coupled to the moveable shutter and drives the moveable shutter. The extent to which electric motor 10 has rotated indicates the extent to which the moveable shutter has moved with the rotation of the electric motor 10. The extent to which the electric motor 10 has rotated is indicated by the number of commutator pulses 74 that have been produced in the voltage signal generated by the current sense resistor R3 and received at the second input interface 34 of the control circuitry 30 following filtering and amplification.

The control circuitry 30 determines the position of the moveable shutter by counting the number of pulses that are received at the second interface 34. A known relationship between the pulses and movement of the shutter enables the position of the shutter to be determined. It may be, for example, that 5 commutator pulses correspond with a millimeter of movement of the shutter.

It is advantageous to be able to determine the position of the shutter for a number of reasons. For example, it may enable the control circuitry 30 to decide when to switch the electric motor 10 from operating in a fast operation mode to operating in a slow operation mode (e.g. when the shutter is approaching its closed position) and vice versa, or when to control the electric motor 10 to cease driving the shutter (e.g. when the shutter is at an extremity of movement, such as its fully open position or its fully closed position).

The apparatus 100 described above is particularly beneficial because it enables a clear commutation pulse reading to be made, irrespective of the speed at which the electric motor 10 is running. If the speed of the electric motor 10 changes, the passband is reset by the control circuitry 30 based on the expected frequency of the commutator pulses, ensuring that the commutator pulses are not inadvertently attenuated by the tunable filter 24.

FIG. 7 illustrates a flow chart of the method described above. At block 301 in FIG. 7, the voltage signal output by the current sense resistor R3 is filtered by the tunable filter arrangement 20. At block 302, at least one electrical parameter is determined that is associated with the electric motor 10.

At block 303, the tunable passband of the tunable filter 24 is set based, at least in part, on the determined at least one electrical parameter. At block 304, the control circuitry 30 determines pulses 74 in the voltage signal that are received at the second input interface 34 of the control circuitry 30. At block 305, a position of the moveable shutter is determined by the control circuitry 30 based on the determined pulses 74.

References to ‘computer-readable storage medium’, ‘control circuitry’, ‘computer’, ‘processor’ etc. should be understood to encompass not only computers having different architectures such as single/multi-processor architectures and sequential (Von Neumann)/parallel architectures but also specialized circuits such as field-programmable gate arrays (FPGA), application specific circuits (ASIC), signal processing devices and other processing circuitry. References to computer program, instructions, code etc. should be understood to encompass software for a programmable processor or firmware such as, for example, the programmable content of a hardware device whether instructions for a processor, or configuration settings for a fixed-function device, gate array or programmable logic device etc.

The blocks illustrated in FIG. 7 may represent steps in a method and/or sections of code in the computer program 36. The illustration of a particular order to the blocks does not necessarily imply that there is a required or preferred order for the blocks and the order and arrangement of the block may be varied. Furthermore, it may be possible for some blocks to be omitted.

Where a structural feature has been described, it may be replaced by means for performing one or more of the functions of the structural feature whether that function or those functions are explicitly or implicitly described.

Although embodiments of the present invention have been described in the preceding paragraphs with reference to various examples, it should be appreciated that modifications to the examples given can be made without departing from the scope of the invention as claimed.

Features described in the preceding description may be used in combinations other than the combinations explicitly described.

Although functions have been described with reference to certain features, those functions may be performable by other features whether described or not.

Although features have been described with reference to certain embodiments, those features may also be present in other embodiments whether described or not.

Whilst endeavoring in the foregoing specification to draw attention to those features of the invention believed to be of particular importance it should be understood that the applicant claims protection in respect of any patentable feature or combination of features hereinbefore referred to and/or shown in the drawings whether or not particular emphasis has been placed thereon.

1. A shutter control apparatus, comprising:
a tunable filter arrangement, having a tunable passband, configured to filter a signal derived at least in part from an electric motor, wherein the electric motor is for driving a moveable shutter and the signal comprises pulses that have a variable frequency and are derived from operation of a commutator of the electric motor; and
control circuitry configured to:
determine at least one electrical parameter associated with the electric motor;
set the tunable passband based, at least in part, on the at least one electrical parameter;
determine pulses in the signal, after the signal has passed through the tunable filter arrangement; and
determine a position of the moveable shutter based on the determined pulses.

2. The shutter control apparatus of claim 1, wherein the tunable passband is set such that the pulses in the signal are maintained when the signal passes through the tunable filter arrangement.

3. The shutter control apparatus of claim 1, wherein the control circuitry is configured to determine the position of the moveable shutter by counting the pulses in the signal.

4. The shutter control apparatus of claim 1, wherein the tunable filter arrangement is configured to attenuate mains ripple in the signal.

5. The shutter control apparatus of claim 4, wherein the tunable filter arrangement comprises a fixed frequency high pass filter configured to attenuate mains ripple in the signal.

6. The shutter control apparatus of claim 1, wherein the tunable filter arrangement is configured to attenuate noise in the signal that is different from the pulses and derived from operation of the commutator of the electric motor.

7. The shutter control apparatus of claim 6, wherein the tunable filter arrangement comprises a tunable filter, with a bandwidth of less than 100 Hz, configured to attenuate the noise in the signal.

8. The shutter control apparatus of claim 1, wherein the at least one electrical parameter is time variable.

9. The shutter control apparatus of claim 1, wherein the control circuitry is configured to: determine a change in the at least one electrical parameter; and to reset the tunable passband in response to the determined change in the at least one electric parameter.

10. The shutter control apparatus of claim 1, wherein the control circuitry is configured to set the tunable passband by referring to a look up table stored in memory.

11. The shutter control apparatus of claim 1, further comprising an n-channel field effect transistor, arranged to modulate electric current supplied to the electric motor, having a source terminal electrically connected to a positive power supply terminal and a drain terminal electrically connected to the electric motor.

12. The shutter control apparatus of claim 1, wherein the at least one electrical parameter includes a voltage parameter.

13. The shutter control apparatus of claim 12, wherein the voltage parameter indicates a supply voltage for the electric motor.

14. The shutter control apparatus of claim 1, wherein the at least one electrical parameter includes an electrical load parameter.

15. The shutter control apparatus of claim 14, wherein the electrical load parameter indicates an electrical load of the electric motor.

16. The shutter control apparatus of claim 1, wherein the at least one electrical parameter includes a pulse width modulation parameter.

17. The shutter control apparatus of claim 16, wherein the pulse width modulation parameter is associated with the modulation of electric current supplied to the electric motor.

18. A method, comprising:
filtering a signal derived at least in part from an electric motor, wherein the electric motor is for driving a moveable shutter and the signal comprises pulses that have a variable frequency and are derived from operation of a commutator of the electric motor;
determining at least one electrical parameter associated with the electric motor;
setting the tunable passband based, at least in part, on the at least one electrical parameter;
determine pulses in the signal, after the signal has passed through the tunable filter arrangement; and
determine a position of the moveable shutter based on the determined pulses.

19. A non-transitory computer readable medium comprising computer program instructions that, when executed by at least one processor, enable the method of claim 18 to be performed.

20. A shutter control apparatus, comprising:
an electric motor, for driving a moveable shutter, having an electric motor current in operation from which a voltage signal is derived that comprises pulses having a variable frequency which are derived from operation of a commutator of the electric motor;
a fixed frequency high pass filter configured to attenuate mains ripple in the voltage signal;
a tunable filter, having a tunable passband, configured to filter the voltage signal after the voltage signal has been filtered by the fixed frequency high pass filter; and
control circuitry configured to:
determine an electric motor supply voltage, an electrical load of the electric motor, and a pulse width modulation parameter associated with the modulation of the electric motor current;
set the tunable passband based on the electric motor supply voltage, the electrical load of the electric motor, and the pulse width modulation parameter associated with the modulation of the electric motor current; and
determine a position of the moveable shutter by counting pulses in the voltage signal after the voltage signal has passed through the tunable filter.
